(19) United States
(12) Patent Application Publication
(10) Pub. No.: US 2026/0004990 A1
(43) Pub. Date: Jan. 1, 2026

(54) LINEAR TCP SOURCE, A CHARGED PARTICLE BEAM SOURCE USING THE LINEAR TCP SOURCE AND A GRID FOR THE CHARGED PARTICLE BEAM SOURCE

(71) Applicant: INFOVION INC., Bucheon-si (KR)

(72) Inventor: Yong Hwan KIM, Goyang-si (KR)

(21) Appl. No.: 18/848,020

(22) PCT Filed: Mar. 3, 2023
(86) PCT No.: PCT/KR2023/002928

§ 371 Date: Apr. 24, 2025

(30) Foreign Application Priority Data
Mar. 29, 2022 (KR) 10-2022-0038536
Feb. 3, 2023 (KR) 10-2023-0014668

(51) Int. Cl. H01J 37/06

(52) U.S. Cl. CPC H01J 37/06; H01J 2237/04732; H01J 2237/083

(57) ABSTRACT

Provided is a large linear TCP source, a large linear charged particle beam source using the plasma source, and a grid for the large linear charged particle beam source. The large linear charged particle beam source includes: a large linear TCP source having at least two unit TCP sources mounted inside a plasma vacuum chamber; a beam body positioned at the front of the TCP source and configured to confine plasma generated from the TCP source; a beam grid positioned at an outlet of the beam body to extract charged particles from the plasma inside the beam body; and an acceleration grid positioned at a predetermined distance away from the beam grid to accelerate the charged particles extracted from the beam grid.

### TECHNICAL FIELD

The present invention relates to a large linear charged particle beam source using a large linear TCP source. More specifically, the present invention relates to a large linear charged particle beam source characterized by mounting a plurality of unit TCP sources inside a plasma vacuum chamber and using a grid configured by connecting a plurality of unit grid modules, a grid for the large linear charged particle beam source, and a large linear TCP source.

### BACKGROUND TECHNOLOGY

Plasma is a group of charged positive ions and electrons generated by an electrical discharge, and includes radicals, which are atomic groups with unpaired excited-state electrons. Since there are actively moving electrons, ions, and radicals inside the plasma, the plasma can cause a chemical reaction that excites or ionizes other substances. In addition, by applying an electric field to the outside of the plasma, the movement speed of the electrons and ions within the plasma can be controlled, leading to physical reactions that cause collisions with other substances. The aforementioned chemical and physical reactions induced by the plasma can be applied not only to the deposition process of a substance, but also to the etching process of a substance.

In general, processing equipment that utilizes plasma includes devices such as PECVD (Plasma Enhanced Chemical Vapor Deposition) for thin-film deposition, etching equipment for patterning by etching the deposited thin film, sputter, ashing equipment, ion beam sources, and electron beam sources. Additionally, these plasma generating devices can be categorized into two types based on how RF power is applied: Capacitively coupled plasma (CCP) devices and Inductively coupled plasma (ICP) devices.

The capacitively coupled plasma device generates plasma by applying RF power formed vertically between opposing parallel plate electrodes and utilizing the RF electric field formed vertically between the electrodes.

On the other hand, in the inductively coupled plasma device, a high-frequency antenna is installed outside the plasma chamber, and a wall as a window between the high-frequency antenna and the plasma processing room is made of a dielectric, allowing plasma processing to be conducted in a vacuum environment. The high-frequency antenna supplies RF power to form the induced electric field inside the plasma chamber. By the induced electric field formed in the plasma chamber, a processing gas introduced into the plasma chamber is ionized into plasma, enabling plasma processing of the substrate. The inductively coupled plasma devices are classified into ICP (Inductively Coupled Plasma), TCP (Transfer Coupled Plasma), Helical Plasma, Helicon Plasma, ECR plasma, etc. based on the shape of the high-frequency antenna and the external magnetic field.

Typically, ICP (Inductively Coupled Plasma) is generated by injecting gas into a tubular plasma chamber made of dielectric material and applying RF power to the antenna wound around the exterior of the tubular plasma chamber. On the other hand, TCP (Transfer Coupled Plasma) is generated by positioning a toroidal antenna, which rotates in a planar shape, behind a plasma window made of flat dielectric material and applying RF power to the antenna. Since the TCP source also generates plasma through induction by high-frequency RF power, it can theoretically be considered a type of ICP source. On the other hand, the ICP source generally has an antenna that rotates along the exterior of a tubular plasma chamber. Therefore, unlike the typical tubular plasma chamber, the ICP source with a flat window and a flat antenna is referred to separately as a TCP source, distinguishing it from the typical tubular chamber configuration.

The aforementioned TCP source is relatively compact among plasma sources and is free from the damage issues that occur in tube-shaped chambers, so it is easy to install and maintain. In addition, the TCP source facilitates generating the more uniform plasma. Therefore, using the TCP source is advantageous when designing a flat-type linear large plasma source.

Meanwhile, there are limitations in the materials available in the market, processing constraints, and physical limitations in creating uniform plasma using a single large antenna. Due to these limitations, it is practically very difficult to produce a plasma source or a charged particle beam source of infinitely large size using a single plasma source. Therefore, by creating basic unit plasma modules of limited size and connecting them in series and parallel configuration, it is possible to scale up the plasma source and charged particle beam source to larger sizes.

FIG. 1 is a cross-sectional view illustrating an ICP (Inductively Coupled Plasma) source according to a conventional patented technology. The ICP source shown in FIG. 1 is disclosed in a patent held by the applicant of the present application, specifically Korean Patent No. 10-2045058. The conventional linear ICP source 1 depicted in FIG. 1 functions a TCP source and includes a ceramic plate 120, an electrode antenna 122, and a cooling water pipe 124. The ceramic plate 120 is composed of an upper plate 1202 and a lower plate 1204, both made of ceramic material, which are bonded together and mounted to the opening of the plasma chamber. The electrode antenna 122 is installed on one surface of the ceramic plate, positioned to face the interior of the plasma chamber. The cooling water pipe 124 is formed on one of the contact surfaces between the upper and lower plates of the ceramic plate, and it is designed to allow cooling water to flow through.

By extending the TCP source shown in FIG. 1 to a linear size, it is possible to create a large-sized linear plasma source. However, if the antenna length is extended indefinitely to increase the size, the power induced in the plasma source along the long linear antenna will eventually encounter physical limits on uniform power induction, particularly in the middle regions of the elongated antenna. As a result, even if the TCP source is made longer, the maximum power that can be applied is inevitably limited. Due to this limitation, when scaling up conventional ICP or TCP sources linearly, the length of the ICP or TCP sources is typically restricted to a maximum of 60 cm to 1 meter.

In addition, in the conventional linear TCP source, the antenna at both ends of the source is bent with a certain curvature, while the antenna in the middle region is extended linearly. As a result, in the conventional linear TCP source, the plasma density in the curved end regions of the antenna differs from the plasma density in the linear middle region of the antenna. Due to this variation in plasma density depending on the position, it is not possible to achieve uniform plasma across the entire length of the source. Consequently, the conventional linear TCP source is inherently limited to being manufactured in a finite size.

FIG. 2 is a schematic diagram of a multi-array configuration of a flange externally mounted TCP linear source according to conventional technology. As shown in FIG. 2, the flange externally mounted TCP linear source 2 provides a large plasma source by fixedly mounting multiple unit TCP sources 28 on the upper surface of the plasma vacuum chamber 20.

The aforementioned conventional flange externally mounted TCP linear source 2 includes a plasma vacuum chamber 20 with multiple openings formed on its upper surface. Unit TCP sources 28 are inserted into the openings on the upper surface of the plasma vacuum chamber 20. Each unit TCP source 28 has a main body 24 and a plasma source flange 26 mounted on the upper surface of the main body 24. The openings in the plasma vacuum chamber are sized to allow the insertion of the main body 24 of the unit TCP source, and the plasma source flange 26 is designed to be larger than the openings in the plasma vacuum chamber. The main body of the unit TCP source is inserted into the openings and positioned inside the plasma vacuum chamber, while the plasma source flange is configured to rest on the outer wall around the openings of the plasma vacuum chamber.

At this time, in order to maintain the interior of the plasma vacuum chamber in a vacuum state, an O-ring 202 is installed between the plasma source flange and the outer wall of the plasma vacuum chamber.

However, due to the regions 204 of the plasma vacuum chamber where the O-rings 202 are installed, plasma discontinuities occur at the connection regions between the unit TCP sources. Despite this, in order to scale up the TCP source, the only feasible approach is to construct the TCP source in modular units of a certain length and connect them either in series or in parallel.

However, as shown in FIG. 2, when multiple unit TCP sources are arranged in an array, O-rings 202 must be installed between the unit modules to connect them in series. The presence of the O-rings 202 and the supporting regions 204 of the plasma vacuum chamber leads to a discontinuity in the plasma, preventing the plasma from connecting continuously. As a result, this causes an issue where the plasma density becomes uneven.

### DETAILED DESCRIPTION OF THE INVENTION

To solve the above-mentioned problems, an object of the present invention is to provide a large linear TCP source configured to ensure uniform plasma formation across the entire system by improving the connection position and connection structure of unit TCP sources.

Another object of the present invention is to provide a large linear charged particle beam source configured to uniformly output a charged particle beam across the entire system using the aforementioned large linear TCP source.

Another object of the present invention is to provide a grid for the large linear charged particle beam source capable of providing a uniform beam flux across the entire system by improving the connection structure of multiple unit grid modules.

In the first aspect of the present invention, a large linear charged particle beam source may comprise: a large linear TCP source mounted inside a vacuum chamber and having at least two unit TCP source modules connected continuously without any discontinuous space; a beam body positioned at the front of the large linear TCP source and configured to confine plasma generated by the large linear TCP source; and, a grid module having multiple grid holes, positioned at an outlet of the beam body and configured to extract charged particles from the plasma inside the beam body.

In the large linear charged particle beam source according to the first aspect of the present invention, it is preferable that the grid module is formed with a double grid structure including a beam grid and an acceleration grid, or a triple grid structure including a beam grid, an acceleration grid, and a deceleration grid, the beam grid has multiple grid holes, is positioned at the outlet of the beam body and is configured to confine plasma and impart energy to charged particles in the plasma, the acceleration grid has multiple grid holes, is positioned at a predetermined distance away from the beam grid and is configured to extract and accelerate the charged particles from the beam grid, and the deceleration grid has multiple grid holes, is positioned at a predetermined distance away from the acceleration grid and is configured to decelerate the charged particles extracted from the acceleration grid.

In the large linear charged particle beam source according to the first aspect of the present invention, it is preferable that the beam grid, the acceleration grid and the deceleration grid are each composed of multiple unit grid modules connected together, with each unit grid module having multiple grid holes, and the multiple unit grid modules are connected using a connection structure based on the shape of the side connection surfaces between adjacent unit grid modules, which the connection structure is one of vertical connection structure, sloped connection structure, stepped connection structure, and a sloped-stepped hybrid connection structure.

In the large linear charged particle beam source according to the first aspect of the present invention, it is preferable that the beam grid, the acceleration grid and the deceleration grid are each composed of multiple unit grid modules connected together, with each unit grid module having grid holes, and the multiple unit grid modules are configured to connect side-surfaces of adjacent unit grid modules in a sloped-stepped hybrid connection structure in which sloped portions and horizontal portions are alternately arranged and the horizontal portions is formed longer than the sloped portions.

In the large linear charged particle beam source according to the first aspect of the present invention, it is preferable that the grid holes of the beam grid, acceleration grid and deceleration grid are arranged in a hexagonal structure, and the adjacent grid holes are positioned at an angle of 30 degrees or 60 degrees relative to the horizontal direction of the beam grid, the acceleration grid and the deceleration grid.

In the large linear charged particle beam source according to the first aspect of the present invention, it is preferable that the grid holes of the beam grid or acceleration grid are configured such that the size of the outlet for the charged particles is equal to or larger than the size of the entrance for the charged particles.

In the large linear charged particle beam source according to the first aspect of the present invention, it is preferable that the large linear charged particle beam source may further comprise a magnetic field reinforcement module which is positioned in a predetermined area inside or outside the plasma vacuum chamber and is configured to supplement the magnetic field in the plasma area.

In the large linear charged particle beam source according to the first aspect of the present invention, it is more preferable that the magnetic field reinforcement module is composed of magnets placed inside or outside the vacuum chamber at the connection portions of the unit TCP sources, or the magnetic field reinforcement module is composed of an electromagnet formed by coils surrounding the outside of the vacuum chamber at the connection portions of the unit TCP sources.

In the large linear charged particle beam source according to the first aspect of the present invention, it is more preferable that the unit grid modules may further comprise additional grid holes placed in an upper or lower region of the connection portion of the unit grid modules, and the additional grid holes are configured to compensate for the grid holes lost at the connection portions of the unit grid modules.

In the large linear charged particle beam source according to the first aspect of the present invention, it is preferable that the large linear TCP source may comprise: a plasma vacuum chamber having a first opening on its upper surface; a vacuum chamber flange having a size larger than the first opening of the plasma vacuum chamber and mounted on the upper surface of the plasma vacuum chamber, and having multiple second openings for mounting unit TCP sources; and multiple unit TCP sources including a main body configured to generate plasma and a source flange mounted on the upper portion of the main body, and wherein the second openings of the vacuum chamber flange are positioned on the upper portion of the source flange of the unit TCP sources and the unit TCP sources are fixedly mounted to the lower surface of the vacuum chamber flange, such that the unit TCP sources are mounted inside the plasma vacuum chamber.

In the second aspect of the present invention, a grid for a large linear charged particle beam source may comprise multiple unit grid modules having multiple grid holes that serve as passage paths for charged particles, wherein the multiple unit grid modules are connected using a connection structure based on the shape of the side connection surfaces between adjacent unit grid modules, which the connection structure is one of vertical connection structure, sloped connection structure, stepped connection structure, and a sloped-stepped hybrid connection structure.

In the grid for the large linear charged particle beam source according to the second aspect of the present invention, it is preferable that the multiple unit grid modules are connected using the sloped-stepped hybrid connection structure where slopped and horizontal portions are alternatively arranged in connection part of adjacent unit grid modules and the horizontal portions are formed longer than the slopped portions.

In the grid for the large linear charged particle beam source according to the second aspect of the present invention, it is preferable that the grid holes of the unit grid module are arranged in a hexagonal structure, and the adjacent grid holes are positioned at an angle of 30 degrees or 60 degrees relative to the horizontal direction of the unit grid module.

In the grid for the large linear charged particle beam source according to the second aspect of the present invention, it is preferable that the grid holes of the unit grid modules are configured such that the size of the outlet for the charged particles is equal to or larger than the size of the entrance for the charged particles.

In the grid for the large linear charged particle beam source according to the second aspect of the present invention, it is preferable that the unit grid modules further comprise additional grid holes positioned in upper or lower regions of the connection portion of the unit grid modules, and the additional grid holes are configured to compensate for the grid holes lost at the connection portions of the unit grid modules.

In the third aspect of the present invention, a large linear TCP source may comprise: a plasma vacuum chamber with a first opening on its upper surface; a vacuum chamber flange having multiple second openings for mounting unit TCP sources, being larger than the first opening of the plasma vacuum chamber and mounted on the upper surface of the plasma vacuum chamber with the first opening; and multiple unit TCP sources including a main body configured to generate plasma and a source flange mounted on the upper portion of the main body, wherein the second openings of the vacuum chamber flange are positioned on the upper portion of the source flange of the unit TCP sources and the unit TCP sources are fixedly mounted to the lower surface of the vacuum chamber flange, such that the unit TCP sources are mounted inside the plasma vacuum chamber.

In the large linear TCP source according to the third aspect of the present invention, it is preferable that the unit TCP source is a TCP source.

In the large linear TCP source according to the third aspect of the present invention, it is preferable that the large linear TCP source may further comprise a magnetic field reinforcement module which is positioned in a predetermined area inside or outside the plasma vacuum chamber to supplement magnetic field in the plasma region.

In the large linear TCP source according to the third aspect of the present invention, it is more preferable that the magnetic field reinforcement module is composed of magnets placed either inside or outside the vacuum chamber at the connection portions of the unit TCP sources, or the magnetic field reinforcement module is composed of electromagnets formed by coils surrounding the outside of the vacuum chamber at the connection portions of the unit TCP sources.

The large linear charged particle beam source according to the present invention can be easily manufactured by connecting unit TCP sources and arranging and connecting unit grid modules corresponding to the unit TCP sources. This allows for manufacturing of a large-scale charged particle beam source with ease.

In addition, the large linear charged particle beam source according to the present invention can provide a uniformly distributed and high beam flux by modifying the connection structure of the unit grid modules, arranging magnetic field reinforcement modules, and altering the shapes of the grid holes.

The large linear charged particle beam source according to the present invention can apply a magnetic field to the plasma by installing magnets or electromagnets inside or outside the plasma vacuum chamber adjacent to the connection portions of unit TCP sources. As a result, the large linear charged particle beam source according to the present invention can increase a local plasma density by applying a magnetic field to the plasma. Through this, the large linear charged particle beam source according to the present invention can compensate for the rapid attenuation of the charged particle beam flux at the connection portions of the unit TCP sources. Consequently, the large linear charged particle beam source according to the present invention can improve the overall uniformity of the charged particle beam flux.

The large linear charged particle beam source according to the present invention can prevent the rapid attenuation of beam flux at the connection portions of unit grid modules by modifying the connection structure of adjacent unit grid modules.

The large linear charged particle beam source according to the present invention compensates for the attenuation of beam flux at the connection portions of the unit grid modules by incorporating additional grid holes in the upper or lower regions of these connection portions. As a result, this design improves the overall uniformity of the charged particle beam flux in the large linear charged particle beam source according to the present invention.

In the large linear charged particle beam source according to the present invention, when a thick grid plate is used, the holes in the beam grid or acceleration grid are designed with sloped, stepped, or a combination of sloped and stepped cross-sectional shapes, so that the outlet of the grid hole can be configured to be wider than the entrance. As a result, even when using the thick grid plate as the grid, this design prevents charged particles from colliding with the walls of the grid holes as they pass through the acceleration grid. Therefore, the large linear charged particle beam source according to the present invention can effectively extract and accelerate the charged particles.

### BRIEF DESCRIPTION OF THE DRAWING

FIG. 1 is a cross-sectional view illustrating a linear plasma source according to a conventional patented technology.

FIG. 2 is a schematic diagram of a multi-array configuration for a TCP linear source having a flange mounted externally according to the prior art.

FIG. 3 is a schematic diagram illustrating a linear TCP source having a flange mounted internally according to the first aspect of the present invention.

FIGS. 4A, 4B, and 4C are a top view, a cross-sectional view, and a bottom view, respectively, illustrating a vacuum plasma chamber and a vacuum chamber flange in the linear TCP source having the flange mounted internally according to the first aspect of the present invention.

FIG. 5 is a schematic diagram illustrating a large linear charged particle beam source using the linear TCP source having a flange mounted internally according to the second aspect of the present invention.

FIG. 6 is a schematic diagram showing the first embodiment of a magnetic field reinforcement module in the large linear charged particle beam source according to the second aspect of the present invention, which is a schematic diagram in the A-B direction of FIG. 5.

FIG. 7 is a cross-sectional diagram showing the second embodiment of a magnetic field reinforcement module in the large linear charged particle beam source according to the second aspect of the present invention, which is a schematic diagram in the A-B direction of FIG. 5.

FIG. 8A is a cross-sectional diagram showing the arrangement of a beam grid and an acceleration grid in contact with plasma in the large linear charged particle beam source according to the second aspect of the present invention, and FIGS. 8B, 8C, 8D and 8E are cross-sectional diagrams showing the examples of the grid holes of the acceleration grid.

FIG. 9A is a cross-sectional view illustrating the arrangement of a beam grid, an acceleration grid, and a deceleration grid in contact with plasma in the large linear charged particle beam source according to the second aspect of the present invention, and FIGS. 9B, 9C, 9D and 9E are cross-sectional views illustrating the examples of the grid holes of the acceleration grid.

FIG. 10A is a plan view showing a vertical connection structure according to a first embodiment of a grid connection structure in a grid for the large linear charged particle beam source according to a third aspect of the present invention, and FIG. 10B is a graph showing a distribution of beam flux for this.

FIG. 11A is a plan view showing a slopped connection structure according to a second embodiment of the grid connection structure in a grid for the large linear charged particle beam source according to the third aspect of the present invention, and FIG. 11B is a graph showing a distribution of beam flux for this.

FIG. 12A is a plan view showing a stepped connection structure according to a third embodiment of the grid connection structure in a grid for the large linear charged particle beam source according to the third aspect of the present invention, and FIG. 12B is a graph showing a distribution of beam flux for this.

FIG. 13A is a plan view showing a sloped-stepped hybrid connection structure according to a fourth embodiment of the grid connection structure in a grid for the large linear charged particle beam source according to the third aspect of the present invention, and FIG. 13B is a graph showing a distribution of beam flux for this. Here, the sloped-stepped hybrid connection structure is a hexagonal structure in which the grid holes are arranged at 60 degrees relative to the left-right linear array direction of the grid holes.

FIG. 14A is a plan view showing a sloped-stepped hybrid connection structure according to the fifth embodiment of the grid connection structure in a grid for the large linear charged particle beam source according to the third aspect of the present invention, and FIG. 14B is a graph showing a distribution of beam flux for this. Here, the sloped-stepped hybrid connection structure is the hexagonal structure in which the grid holes are arranged at 30 degrees relative to the left-right linear array direction of the grid holes.

FIG. 15 is a schematic diagram showing additional grid holes for supplementing grid holes lost at connection portions of unit grid modules in the grid for the large linear charged particle beam source according to the third aspect of the present invention.

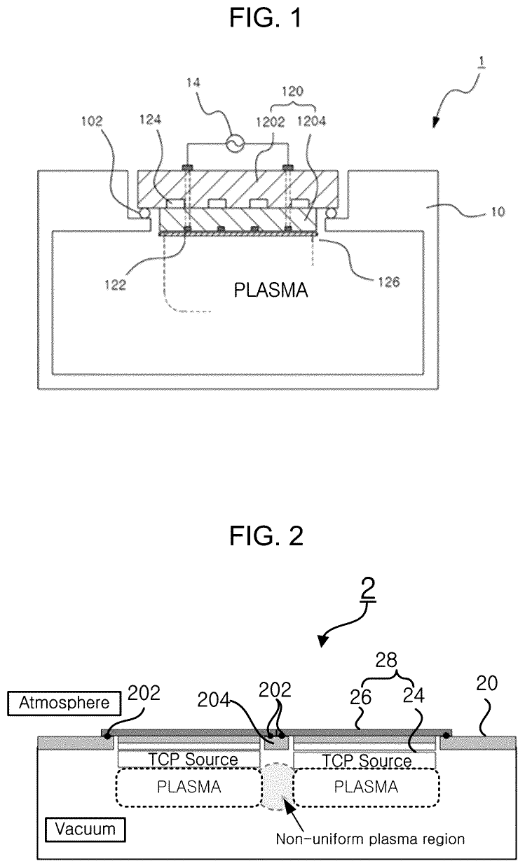

### BEST MODE FOR CARRYING OUT THE INVENTION

### <Large Linear TCP Source>

A large linear TCP source according to the first aspect of the present invention is characterized in that multiple unit TCP sources are arranged, and flanges of the unit TCP sources are mounted inside a plasma vacuum chamber. In a conventional plasma source, the flanges of the unit TCP sources are mounted outside the plasma vacuum chamber. However, unlike the conventional plasma source, the large linear TCP source according to the first aspect of the present invention mounts the unit TCP sources inside the plasma vacuum chamber. Accordingly, the large linear TCP source according to the first aspect of the present invention can uniformly generate plasma across the entire system. Hereinafter, the structure and operation of the large linear TCP source according to the first aspect of the present invention will be described with reference to the attached drawings.

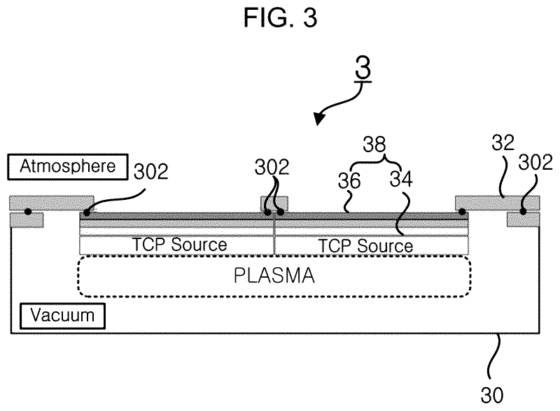

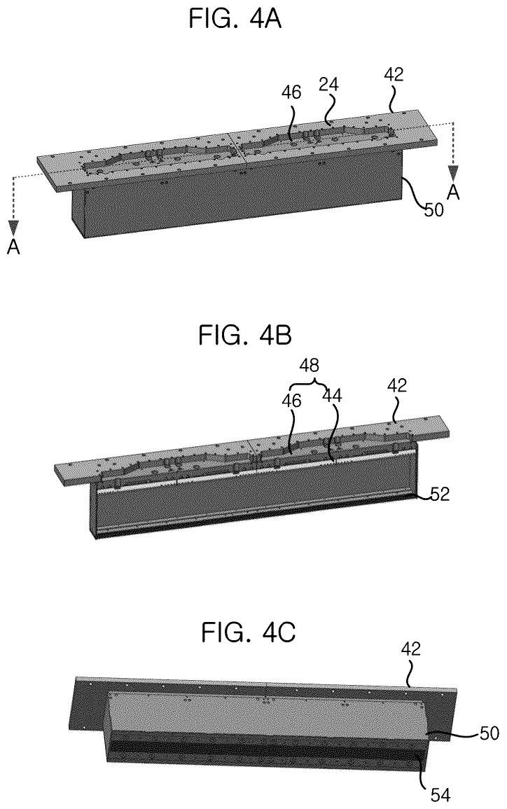

FIG. 3 is a schematic diagram illustrating a linear TCP source having a flange mounted internally according to the first aspect of the present invention, in which multiple linear TCP sources are arranged. In addition, FIGS. 4A, 4B, and 4C are a top view, a cross-sectional view, and a bottom view, respectively, illustrating a vacuum plasma chamber and a vacuum chamber flange in the linear TCP source having the flange mounted internally according to the first aspect of the present invention. Referring to FIG. 3, the large linear TCP source 3 according to the first aspect of the present invention includes a plasma vacuum chamber 30, a vacuum chamber flange 32, and multiple unit TCP sources 38.

The plasma vacuum chamber 30 is provided with a first opening on its upper surface.

The vacuum chamber flange 32 is configured to be larger than the first opening of the plasma vacuum chamber, allowing the first opening to be positioned beneath the vacuum chamber flange. A sealing member 302, such as an O-ring, is placed at the connection portion of the plasma vacuum chamber and the vacuum chamber flange. This sealing member ensures that the interior of the plasma vacuum chamber is maintained in a vacuum state.

The vacuum chamber flange 32 has multiple second openings designed to accommodate the mounting of the unit TCP sources 38.

The multiple unit TCP sources 38 consist of a main body 34 that generates plasma and a source flange 36 mounted on the upper part of the main body. The main body and the source flange of the unit TCP source can be of the same size.

It is preferable that the source flange 36 of the unit TCP source is configured to be larger than the second opening of the vacuum chamber flange, and that the second openings of the vacuum chamber flange are positioned over the source flanges.

It is preferable that the multiple unit TCP sources are sequentially connected such that their sides are in contact with each other. The multiple second openings of the vacuum chamber flange are positioned on the upper surface of the source flanges of the multiple unit TCP sources, and the unit TCP sources and the second openings can be arranged to correspond one-to-one with each other.

The sealing member 302, such as an O-ring, is placed at the connection portion between the source flange of the unit TCP source and the vacuum chamber flange, so as to maintain the inside of the plasma vacuum chamber in a vacuum state.

With the aforementioned structure, the large linear TCP source according to the first aspect of the present invention allows the connection portions of adjacent unit TCP sources to be mounted in contact with each other inside the plasma vacuum chamber. As a result, the arrangement of the unit TCP sources according to the present invention, which make up the large linear TCP source, can be seamlessly continuous. This structure of the plasma source according to the present invention can solve the problems of plasma discontinuities that occur in conventional TCP linear sources having a flange mounted externally. Consequently, the present invention can provide the large linear TCP source capable of generating plasma uniformly across the entire system.

### <Large Linear Charged Particle Beam Source Using Linear TCP Source>

Hereinafter, the structure and operation of the large linear charged particle beam source according to the second aspect of the present invention will be described with reference to the attached drawings.

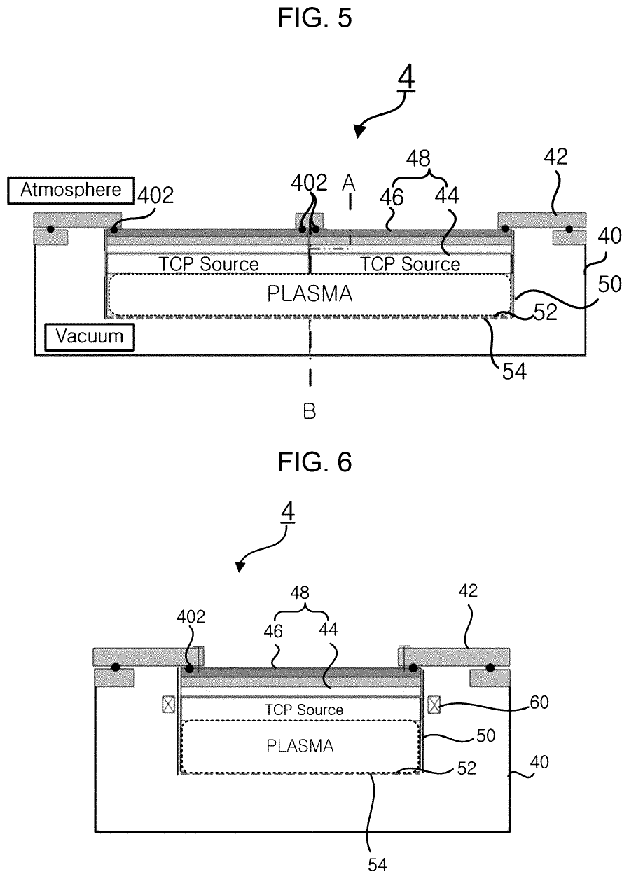

FIG. 5 is a schematic diagram illustrating a large linear charged particle beam source using the linear TCP source having a flange mounted internally according to the second aspect of the present invention.

Referring to FIG. 5, the large linear charged particle beam source 4 according to the second aspect of the present invention comprises a large linear TCP source, a beam body 50, and a grid module. The large linear TCP source is composed of unit TCP sources 48, with the source flanges 46 mounted inside the plasma vacuum chamber 40. The unit TCP sources are connected in series, with their sides in contact with each other, forming a continuous structure.

The grid module has multiple grid holes and is positioned at the outlet of the beam body, allowing charged particles to be extracted from the plasma within the beam body. The grid module can be composed of either a dual-grid structure, consisting of a beam grid 52 and an acceleration grid 54, or a triple-grid structure, including a beam grid, an acceleration grid, and a deceleration grid. The beam grid 52 has multiple grid holes and is positioned at the outlet of the beam body.

The beam grid 52 can confine the plasma inside the beam body and can impart energy to the charged particles within the plasma. The acceleration grid 54, also with multiple grid holes, is positioned a certain distance away from the beam grid. The acceleration grid 54 can extract and accelerate the charged particles from the beam grid. The deceleration grid (not shown), also containing multiple grid holes, is placed a certain distance away from the acceleration grid. The deceleration grid can slow down the charged particles that have been extracted and accelerated by the acceleration grid.

The large linear TCP source of the large linear charged particle beam source according to the second aspect of the present invention can utilize the large linear TCP source according to the first aspect described above. Additionally, the beam grid 52, the acceleration grid 54, and the deceleration grid of the large linear charged particle beam source according to the second aspect of the present invention can apply the grid for the large linear charged particle beam source according to the third aspect of the present invention, which will be discussed later.

The beam body 50 can be configured to confine the plasma generated by the electrode antenna of the large linear TCP source. It is preferable that the beam body is made of a metallic material.

The beam grid 52 is positioned at the outlet of the beam body 50, just before the acceleration grid. The beam grid 52 is capable of imparting energy to the charged particles, such as ions or electrons, present in the plasma inside the beam body. The acceleration grid 54 is located at a certain distance away from the front of the beam grid. The acceleration grid 54 can extract and accelerate the charged particle beam, such as ions or electrons, that has been extracted from the beam grid.

At this time, the beam grid can provide energy that can provide the speed at which the charged particle beam flies by connecting a power source having the same polarity as the extracted charged particles. The acceleration grid can provide potential energy that can extract and accelerate the charged particle beam from the plasma by connecting a power source having the opposite polarity to the charged particles. In the case of having a triple grid, a deceleration grid can be additionally provided.

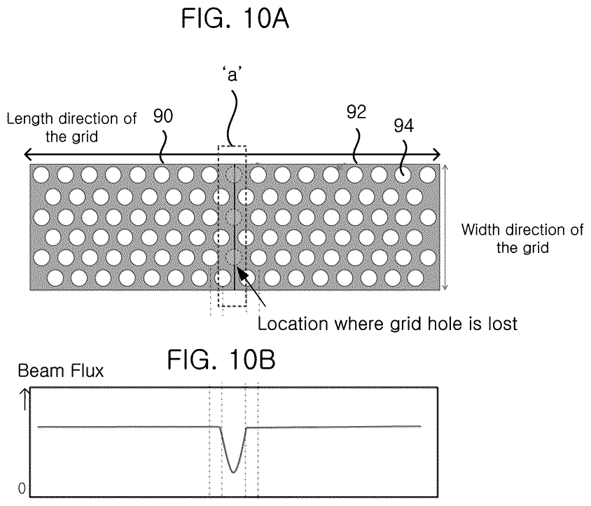

The beam grid and acceleration grid can be composed of the grid structure for the large linear charged particle beam source, as described later with reference to FIGS. 10 to 15. The grid for the large linear charged particle beam source according to the present invention can be configured by sequentially connecting multiple unit grid modules.

When the unit TCP sources are connected in series, the connection portions of the dielectric blocks of the unit TCP sources are located at positions significantly distanced from the center of the antenna. As a result, these connection portions experience reduced RF induction from the antenna, leading to a decrease in beam flux. Therefore, to maintain precise uniformity of the charged particle beam flux across the entire area along the left and right directions of the array, the beam flux at the connection portions of the unit TCP sources must be compensated. To address this issue, the large linear TCP source and large linear charged particle beam source according to the first and second aspects of the present invention preferably include a magnetic field reinforcement module configured to supplement the magnetic field in the plasma region. This magnetic field reinforcement module can be composed of magnets with N-S poles or electromagnets using coils. The magnetic field reinforcement module ensures that the beam flux provided by the large linear TCP source maintains high uniformity across the entire system.

FIG. 6 is a cross-sectional view illustrating a first embodiment of a magnetic field reinforcement module in the A-B direction of FIG. 5 in the large linear charged particle beam source according to the second aspect of the present invention. Referring to FIG. 6, the first embodiment of the magnetic field reinforcement module 60 according to the present invention is positioned in the upper region of the side of the beam body inside the plasma vacuum chamber, specifically at the connection portions of the unit TCP sources. Magnets are placed on both sides of the beam body inside the plasma vacuum chamber, with the N-pole and S-pole facing each other, thereby applying the magnetic field to the plasma region.

As a result, the magnetic field applied by the magnets increases the plasma density locally in the region where the magnetic field is applied. The enhanced plasma density due to the influence of the magnetic field leads to an increase in the number of charged particles, such as electrons and ions, within the plasma. Consequently, the flux of the charged particle beam emitted through the beam grid and acceleration grid also increases. By using the magnetic field reinforcement module to apply additional magnetic fields at the connection portions of the unit TCP sources, the local plasma density can be increased. This, in turn, improves the uniformity of the charged particle beam flux emitted through the beam grid and acceleration grid, ensuring more consistent beam output across the system.

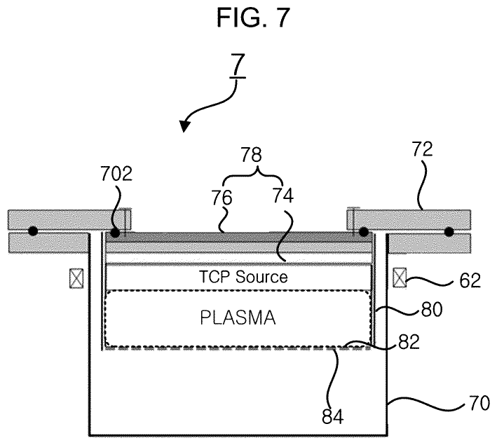

FIG. 7 is a cross-sectional view illustrating a second embodiment of the magnetic field reinforcement module in the A-B direction of FIG. 5 in the large linear charged particle beam source according to the second aspect of the present invention. Referring to FIG. 7, the second embodiment of the magnetic field reinforcement module 62 according to the present invention is placed outside the plasma vacuum chamber 70, specifically near the connection portions of the unit TCP sources 78. In this case, the magnetic field reinforcement module 62 can either consist of magnets placed outside the plasma vacuum chamber or be composed of an electromagnet made of coils that surround the charged particle beam source.

As shown in FIG. 7, even when the outer wall of the plasma vacuum chamber, which constitutes the large linear charged particle beam source 7, is positioned close to the side of the plasma source, magnets can be installed on the outer wall of the plasma vacuum chamber 70 to locally increase the flux of the charged particle beam. As a result, high uniformity of the overall beam flux in the large linear charged particle beam source can be achieved.

Even if, as shown in FIG. 7, a coil is wound around the large linear charged particle beam source to form an electromagnet or permanent magnets are placed around it to increase the overall charged particle beam flux, additional magnets can still be placed at the connection portions of the unit TCP sources. This would further increase the local plasma density in those regions, thereby enhancing the beam flux while simultaneously achieving high uniformity across the entire system.

When using the large linear charged particle beam source to irradiate a thin film on a substrate and control its properties, the thin film may sometimes be highly sensitive to the charged particle beam flux upon impact. In such cases, the uniformity of the beam flux is critically important. One example is the thermal treatment of an IGZO (Indium Gallium Zinc Oxide) film, which forms an oxide TFT, using an electron beam. In this scenario, the uniformity of the electron beam directly influences the thermal treatment results across the entire area of the large substrate. The outcome of this thermal treatment ultimately determines the uniformity of the TFT performance on the large substrate. Thus, it is crucial that the design of the large linear charged particle beam source ensures a high degree of uniformity in the charged particle beam flux.

In the large linear charged particle beam source according to the second aspect of the present invention, the beam grid and the acceleration grid can each apply the grid for the large linear charged particle beam source described later. The grid holes of the beam grid and acceleration grid must be precisely aligned with each other. It is preferable that the grid for the large linear charged particle beam source is constructed by sequentially connecting multiple unit grid modules to correspond to the size of the large linear TCP source. FIGS. 10 to 14 are schematic diagrams exemplifying various embodiments of the connection structure of the unit grid modules in the grid for the large linear charged particle beam source according to the third aspect of the present invention. A specific description of the grid for the large linear charged particle beam source according to the present invention will be described later with reference to FIGS. 10 to 15.

In general, when the large linear charged particle beam source is operated or used for an extended period, the grid tends to heat up. When the grid heats up, deformation of the grid can occur. If such grid deformation occurs, the spacing between the unit grid modules used in the large linear charged particle beam source may become uneven. As a result, the required uniformity of the beam flux may not be achieved. Therefore, by using the thick grid plate that exhibits strong resistance to thermal deformation, it is possible to prevent the grid from deforming due to heat.

However, when a thick grid plate is used, the thickness of the grid plate can affect the extraction of charged particles. As a result, the beam flux may be decreased, or the flight path of the beam could be altered.

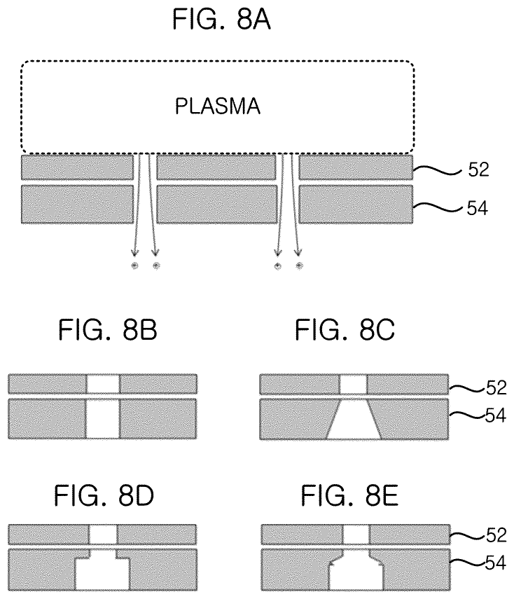

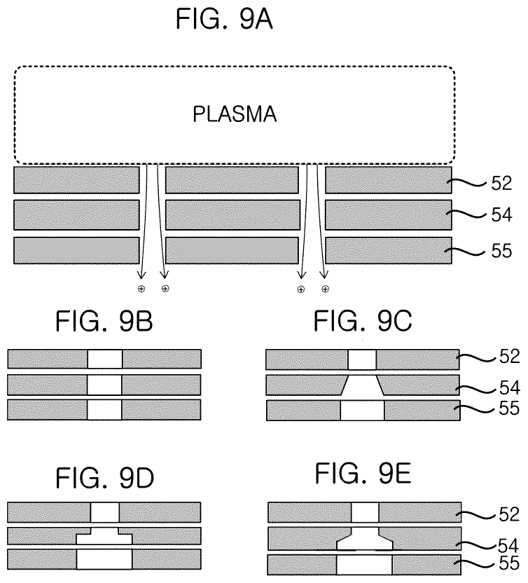

FIGS. 8A to 8E and 9A to 9E are schematic diagrams illustrating the shapes of charged particles traveling through a beam grid, an acceleration grid, and a deceleration grid in the large linear charged particle beam source according to the second aspect of the present invention, and cross-sectional views exemplarily illustrating various embodiments of the acceleration grid composed of a thick grid plate.

Referring to FIGS. 8A and 9A, in the large linear charged particle beam source, the beam grid 52 and acceleration grid 54 are arranged vertically with a consistent gap between them. The beam grid 52 may be connected to a power source in order to apply a voltage to the plasma, thereby shielding the plasma and energizing the charged particles. The acceleration grid 54 may be connected to a power source in order to extract and accelerate charged particles, such as ions or electrons, from the plasma. In this configuration, the grid holes of the beam grid and the acceleration grid are precisely aligned and positioned in front of the plasma to ensure the efficient extraction and acceleration of charged particles.

Referring to FIGS. 8B to 8E and 9A to 9E, the grid holes in the acceleration grid 54, which is made of a thick grid plate, can have various cross-sectional shapes, including vertical, sloped, stepped, or a combination of sloped and stepped forms. Specifically, even when a thick grid plate is used, the grid holes can be designed with a sloped, stepped, or combination of sloped and stepped shape, so that the outlet of the grid hole can be wider than the entrance. This design can prevent charged particles from colliding with the grid while passing through the beam grid or acceleration grid holes, enabling efficient extraction and flight of the particles. Thus, it is preferable for the cross-sectional shape of the grid holes to be sloped, stepped, or combination of sloped and stepped rather than vertical, as this ensures that the outlet is wider than the entrance. This configuration can be applied not only to the acceleration grid but also to the beam grid.

### <Grid for a Large Linear Charged Particle Beam Source>

A large linear charged particle beam source according to the second aspect of the present invention comprises the beam grid and the acceleration grid for extracting and accelerating the charged particle beam at the outlet of a beam body, as illustrated in FIG. 5. The beam grid and the acceleration grid of the large linear charged particle beam source according to the second aspect of the present invention maintain a constant spacing between each other, and the grid holes of the beam grid and the grid holes of the acceleration grid are precisely aligned and positioned.

Additionally, it is practically impossible to manufacture the beam grid and acceleration grid used in the large linear charged particle beam source according to the present invention in a single piece matching the size of the charged particle beam source. Therefore, the grid for the large linear charged particle beam source in the third aspect of the present invention can be constructed by connecting unit grid modules 90, 92 of predetermined sizes in series or parallel configurations. These modular grids can be applied to the beam grid and acceleration grid of the large linear charged particle beam source in the second aspect of the present invention.

The grid for the large linear charged particle beam source is typically made from metals such as Mo (Molybdenum), Ti (Titanium), Ta (Tantalum), or materials like glassy carbon. When the grid undergoes thermal expansion due to heat generated by the plasma, deformation of the grid plate can occur. This deformation can lead to electrical shorting between the beam grid and acceleration grid, which are positioned close to each other. To prevent this issue, it is important to use materials that are resistant to heat for the grid. Furthermore, since many holes must be drilled in the grid for use as grid holes, the material chosen must have excellent machinability and should not undergo deformation during the fabrication process.

As described above, the grid for the large linear charged particle beam source according to the present invention can be constructed by connecting unit grid modules in series or parallel, taking into consideration the required material properties and processing issues as described above.

Meanwhile, the unit grid module must allow for the maximum beam flux to pass through its grid holes. Therefore, it is desirable to configure the unit grid module to have the maximum transmittance by maximizing the number of grid holes, while ensuring the material remains resistant to deformation. In order to maximize the number of grid holes, the unit grid module can be configured to have unit cells in which the grid holes are arranged in a hexagonal pattern. In addition, the grid for the large linear charged particle beam source according to the present invention can be configured by connecting the unit grid modules.

Hereinafter, with reference to FIGS. 10 to 14, various embodiments of the connection structure of the grid for the large linear charged particle beam source according to the third aspect of the present invention will be described.

FIG. 10A is a plan view showing a vertical connection structure according to a first embodiment of the grid connection structure in the grid for the large linear charged particle beam source according to the third aspect of the present invention, and FIG. 10B is a graph showing a distribution of beam flux for this.

Referring to FIG. 10, the first embodiment of the grid connection structure can form a grid for the charged particle beam source by machining the opposite ends of the unit grid modules 90, 92 into a vertical shape and connecting the unit grid modules of the vertical shape. In this case, during the machining, the grid holes of the end portion (area ‘a’) of the unit grid module may not form a perfect semicircle or could become distorted. In addition, even if the unit grid modules are aligned face to face and connected, it is difficult to achieve perfectly circular grid holes at the connection portions, leading to potential imperfections in the grid's shape.

To solve these problems, machining the grid holes positioned at both ends of the unit grid modules to maintain their original shape makes the alignment process much easier.

In addition, as illustrated in FIG. 10, in the first embodiment of the grid connection structure, the grid holes at the connection portion (area ‘a’) of the unit grid modules 90, 92 are lost, and as a result, the beam flux at the connection portions of the unit grid modules decreases significantly.

Meanwhile, when the large linear charged particle beam source according to the present invention is used to irradiate a charged particle beam to a large substrate, the beam is irradiated while moving the large substrate in a direction perpendicular to the longitudinal direction of the grid, that is, along the width direction of the grid. At this time, in the substrate area passing through the connection portions of the unit grid modules where the beam flux drops sharply, the beam processing results in an uneven result.

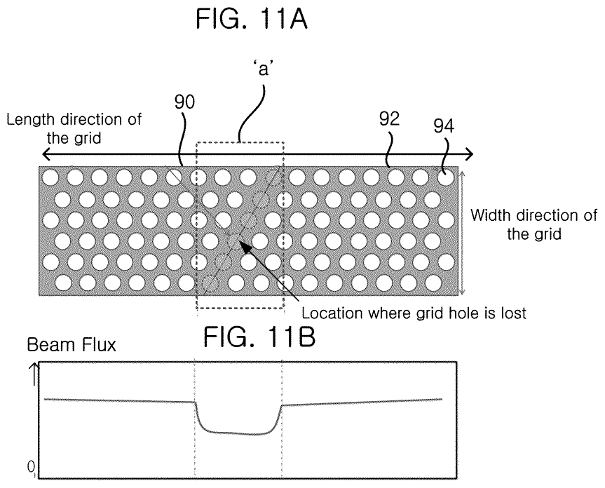

As described above, in order to solve the problem of the significant decrease in beam flux at the side connection portions of the unit grid modules, the present invention proposes various improved configurations, including sloped, stepped, and sloped-stepped hybrid structures, as illustrated in FIGS. 11 to 14.

FIG. 11A is a plan view showing a slopped connection structure according to a second embodiment of the grid connection structure in a grid for the large linear charged particle beam source according to the third aspect of the present invention, and FIG. 11B is a graph showing a distribution of beam flux for this. Referring to FIGS. 11A and 11B, the sloped connection structure of the unit grid modules features unit grid modules with sloped ends. The connection portions of the unit grid modules are also sloped.

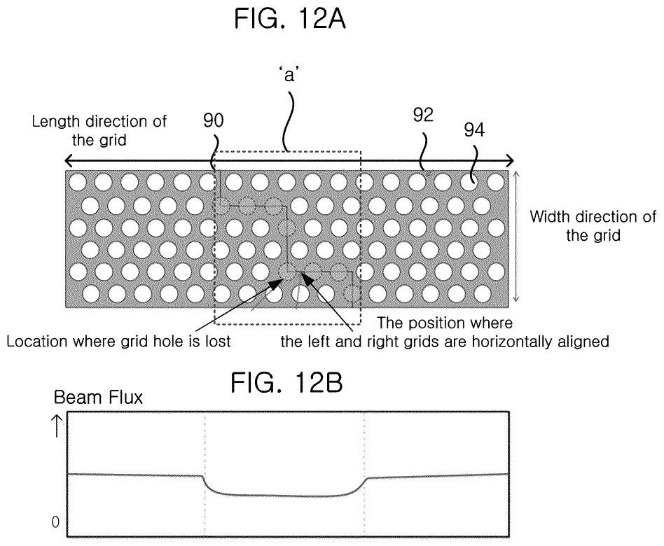

FIG. 12A is a plan view showing a stepped connection structure according to a third embodiment of the grid connection structure in a grid for the large linear charged particle beam source according to the third aspect of the present invention, and FIG. 12B is a graph showing a distribution of beam flux for this. Referring to FIGS. 12A and 12B, the stepped grid connection structure features unit grid modules with stepped ends. The connection portions of the unit grid modules are also formed in a stepped shape.

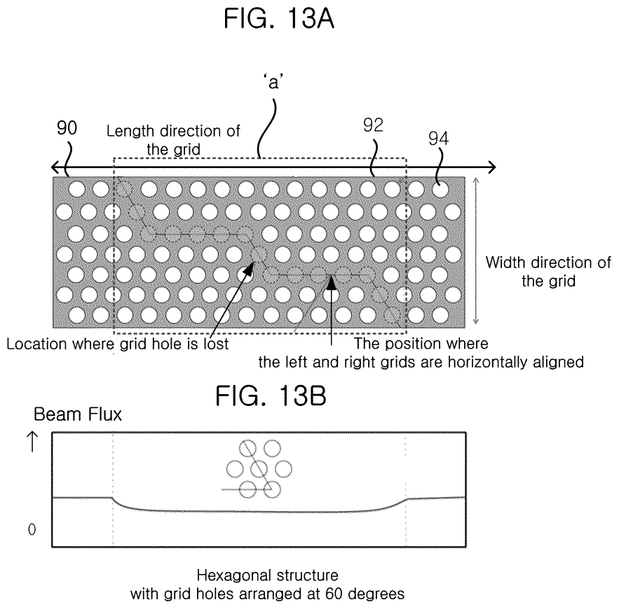

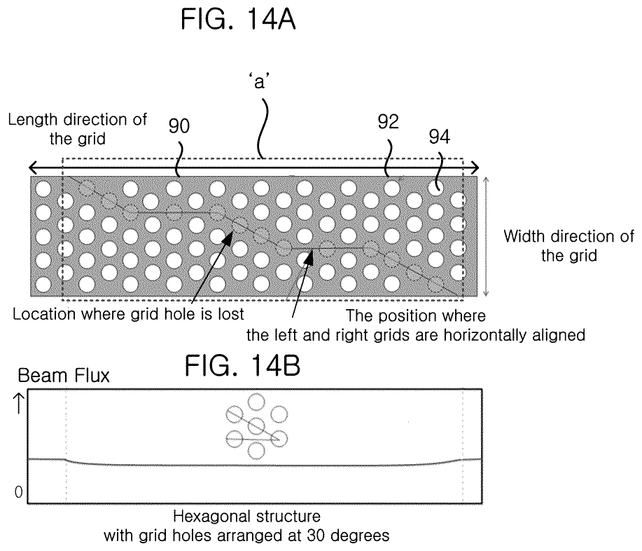

FIG. 13A is a plan view showing a sloped-stepped hybrid connection structure according to a fourth embodiment of the grid connection structure in the grid for the large linear charged particle beam source according to the third aspect of the present invention, and FIG. 13B is a graph showing a distribution of beam flux for this. The fourth embodiment of the grid connection structure is characterized by having a hexagonal structure in which grid holes are arranged at 60 degrees to the longitudinal direction of the grid. FIG. 14A is a plan view showing a sloped-stepped hybrid connection structure according to the fifth embodiment of the grid connection structure in the grid for the large linear charged particle beam source according to the third aspect of the present invention, and FIG. 14B is a graph showing a distribution of beam flux for this. The fifth embodiment of the grid connection structure is characterized by having a hexagonal structure in which grid holes are arranged at 30 degrees to the longitudinal direction of the grid.

Referring to FIGS. 13 and 14, the sloped-stepped hybrid connection structure of the grid in the large linear charged particle beam source according to the present invention is characterized in that the ends of the unit grid modules are connected to each other in an alternating pattern of sloped and horizontal sections.

Unlike the vertical connection structure of the unit grid modules, the grid connection structures according to the various embodiments of the present invention described above can maximize the length of the contacting portions of the unit grid modules. As a result, the problem of the flux of the charged particle beam measured along the left-right direction from below the grid suddenly and sharply dropping at the connection portions of the unit grid modules can be solved.

Meanwhile, the circular grid holes indicated by dotted lines in the drawing represent grid holes lost at the connection portions of the unit grid modules. The configuration that minimizes the number of lost grid holes per unit area at these connection portions is the sloped-stepped hybrid grid connection structure with the grid holes arranged at a 30-degree angle in a hexagonal pattern, as shown in FIG. 14. In this sloped-stepped hybrid grid structure, the shorter the sloped sections and the longer the horizontally aligned sections, the greater the contact length at the connection portions. Accordingly, it can be seen that as the length of the contact area of the connection portion increases, the number of grid holes lost per unit area decreases. Compared to the fourth embodiment (FIG. 13) in which the grid holes are arranged at an angle of 60 degrees with respect to the longitudinal direction as a regular hexagonal structure, the fifth embodiment (FIG. 14) in which the grid holes are arranged at an angle of 30 degrees can reduce the number of grid holes lost per unit area at the connection portion. Consequently, the fifth embodiment of the grid connection structure is more preferable than the fourth embodiment.

As described above, in the grid connection structure, the area where adjacent unit grid modules contact each other along the horizontal direction is maximized, and the grid holes are arranged at a 30-degree angle in the hexagonal structure, so that the number of grid holes lost per unit area at the connection portion can be minimized. Through this structure, it is possible to minimize the rapid decrease in the flux of the charged particle beam at the grid connection portion.

In addition, in the aforementioned sloped-stepped hybrid grid connection structure, it is more preferable to shorten the sloped sections and extend the horizontal sections, thereby maximizing the contact area between the unit grid modules along the horizontal direction. In addition, when the length of the contact area between adjacent unit grid modules is maximized, the number of grid holes lost per unit area at the connection portions is minimized. Therefore, the most favorable structure is the sloped-stepped hybrid grid connection where the sloped section is composed of two grid holes.

In the present invention, by maximizing the length of the connection portions of the unit grid modules, the problem of lost grid holes at the connection portions can be minimized. This approach also minimizes the attenuation of the beam flux at the connection portions, ultimately leading to a significant improvement in the uniformity of the charged particle beam irradiation.

In the sloped-stepped hybrid grid connection structure, the longer the connection portion in the horizontal direction, the less the beam flux attenuation at the lower part of the connection portions. As a result, this design maximizes the improvement in beam uniformity.

In summary, the grid for the large linear charged particle beam source according to the third aspect of the present invention is characterized by being configured by connecting the unit grid modules laterally in series or in parallel continuously. In particular, the grid for the large linear charged particle beam source according to the present invention is most preferably configured such that the unit grid modules are connected in a sloped-step hybrid grid connection structure. Furthermore, in the sloped-step hybrid grid connection structure, it is more desirable that the horizontal stepped sections are wider than the sloped sections.

Meanwhile, in the grid for the large linear charged particle beam source according to the third aspect of the present invention, the beam flux may decrease due to the loss of the grid holes at the connection portions of the unit grid modules. Therefore, the beam flux can be compensated by placing additional grid holes in a predetermined area around the connection portions of the unit grid modules.

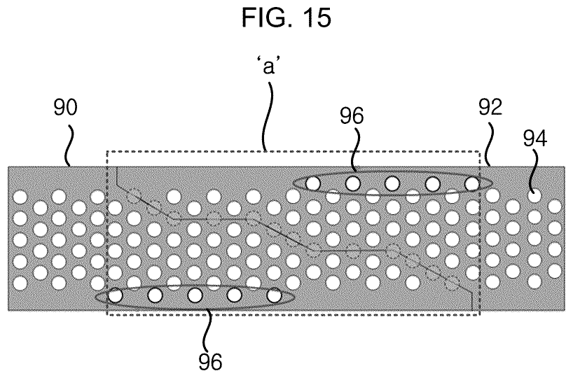

FIG. 15 is a schematic diagram of a grid for the large linear charged particle beam source according to the third aspect of the present invention, in which additional grid holes are placed to compensate for lost grid holes at connection portions of unit grid modules. As illustrated in FIG. 15, the additional grid holes 96 can be positioned in the upper or lower areas of the original grid hole locations that are lost at the connection portions of the unit grid modules.

When a large substrate is beam-processed using the large linear charged particle beam source, the large linear charged particle beam source is usually fixed to the plasma vacuum chamber, and the substrate under the large linear charged particle beam source moves at a constant speed along a direction perpendicular to the grid, so that the charged particle beam is irradiated toward the substrate. As the charged particle beam is directed toward the substrate, the additional grid holes located at the upper or lower ends of the grid compensate for the beam flux lost due to the missing grid holes at the connection portions of the unit grid modules. As a result, the charged particle beam emitted from these additional grid holes helps to maintain uniform beam processing across the substrate.

Although the present invention has been described above with reference to preferred embodiments thereof, these are merely examples and do not limit the scope of the present invention. It will be understood by those skilled in the art that various modifications and applications not explicitly illustrated in the above examples may be made without departing from the essential characteristics of the invention. Any differences related to these modifications and applications should be interpreted as falling within the scope of the invention as defined by the appended claims.

The large linear charged particle beam source according to the present invention can be easily manufactured by connecting unit TCP sources to each other and connecting and arranging unit grid modules.

What is claimed is:

1. A large linear charged particle beam source comprising:
a large linear TCP source mounted inside a vacuum chamber and having at least two unit TCP source modules connected continuously without any discontinuous space;
a beam body positioned at the front of the large linear TCP source and configured to confine plasma generated by the large linear TCP source; and
a grid module having multiple grid holes, positioned at an outlet of the beam body and configured to extract charged particles from the plasma inside the beam body.

2. The large linear charged particle beam source according to claim 1, wherein the grid module is formed with a double grid structure including a beam grid and an acceleration grid, or a triple grid structure including a beam grid, an acceleration grid, and a deceleration grid,
the beam grid has multiple grid holes, is positioned at the outlet of the beam body and is configured to confine plasma and impart energy to charged particles in the plasma,
the acceleration grid has multiple grid holes, is positioned at a predetermined distance away from the beam grid and is configured to extract and accelerate the charged particles from the beam grid, and
the deceleration grid has multiple grid holes, is positioned at a predetermined distance away from the acceleration grid and is configured to decelerate the charged particles extracted from the acceleration grid.

3. The large linear charged particle beam source according to claim 2, wherein the beam grid, the acceleration grid and the deceleration grid are each composed of multiple unit grid modules connected together, with each unit grid module having multiple grid holes, and
the multiple unit grid modules are connected using a connection structure based on the shape of the side connection surfaces between adjacent unit grid modules, which the connection structure is one of vertical connection structure, sloped connection structure, stepped connection structure, and a sloped-stepped hybrid connection structure.

4. The large linear charged particle beam source according to claim 2, wherein the beam grid, the acceleration grid and the deceleration grid are each composed of multiple unit grid modules connected together, with each unit grid module having grid holes, and
the multiple unit grid modules are configured to connect side-surfaces of adjacent unit grid modules in a sloped-stepped hybrid connection structure in which sloped portions and horizontal portions are alternately arranged and the horizontal portions is formed longer than the sloped portions.

5. The large linear charged particle beam source according to claim 2, wherein the grid holes of the beam grid, acceleration grid and deceleration grid are arranged in a hexagonal structure, and
the adjacent grid holes are positioned at an angle of 30 degrees or 60 degrees relative to the horizontal direction of the beam grid, the acceleration grid and the deceleration grid.

6. The large linear charged particle beam source according to claim 2, wherein the grid holes of the beam grid or acceleration grid are configured such that the size of the outlet for the charged particles is equal to or larger than the size of the entrance for the charged particles.

7. The large linear charged particle beam source according to claim 2, wherein the grid holes of the beam grid or acceleration grid are formed with either a slopped or stepped cross-sectional structure, or a cross-sectional structure that is a combination of slopped and stepped shapes.

8. The large linear charged particle beam source according to claim 1, further comprising a magnetic field reinforcement module which is positioned in a predetermined area inside or outside the plasma vacuum chamber and is configured to supplement the magnetic field in the plasma area.

9. The large linear charged particle beam source according to claim 8, wherein the magnetic field reinforcement module is composed of magnets placed inside or outside the vacuum chamber at the connection portions of the unit TCP sources, or
the magnetic field reinforcement module is composed of an electromagnet formed by coils surrounding the outside of the vacuum chamber at the connection portions of the unit TCP sources.

10. The large linear charged particle beam source according to claim 3, wherein the unit grid modules further comprise additional grid holes placed in an upper or lower region of the connection portion of the unit grid modules, and
the additional grid holes are configured to compensate for the grid holes lost at the connection portions of the unit grid modules.

11. The large linear charged particle beam source according to claim 1, wherein the large linear TCP source comprises:
a plasma vacuum chamber having a first opening on its upper surface;
a vacuum chamber flange having a size larger than the first opening of the plasma vacuum chamber and mounted on the upper surface of the plasma vacuum chamber, and having multiple second openings for mounting unit TCP sources; and
multiple unit TCP sources including a main body configured to generate plasma and a source flange mounted on the upper portion of the main body, and
wherein the second openings of the vacuum chamber flange are positioned on the upper portion of the source flange of the unit TCP sources and the unit TCP sources are fixedly mounted to the lower surface of the vacuum chamber flange, such that the unit TCP sources are mounted inside the plasma vacuum chamber.

12. A grid for a large linear charged particle beam source, comprising multiple unit grid modules having multiple grid holes that serve as passage paths for charged particles,
wherein the multiple unit grid modules are connected using a connection structure based on the shape of the side connection surfaces between adjacent unit grid modules, which the connection structure is one of vertical connection structure, sloped connection structure, stepped connection structure, and a sloped-stepped hybrid connection structure.

13. The grid for the large linear charged particle beam source according to claim 12, wherein the multiple unit grid modules are connected using the sloped-stepped hybrid connection structure where slopped and horizontal portions are alternatively arranged in connection part of adjacent unit grid modules and the horizontal portions are formed longer than the slopped portions.

14. The grid for the large linear charged particle beam source according to claim 12, wherein the grid holes of the unit grid module are arranged in a hexagonal structure, and
the adjacent grid holes are positioned at an angle of 30 degrees or 60 degrees relative to the horizontal direction of the unit grid module.

15. The grid for the large linear charged particle beam source according to claim 12, wherein the grid holes of the unit grid modules are configured such that the size of the outlet for the charged particles is equal to or larger than the size of the entrance for the charged particles.

16. The grid for the large linear charged particle beam source according to claim 15, wherein the grid holes of the unit grid module are formed with either slopped or stepped cross-sectional structure, or
the grid holes of the unit grid module are formed with a cross-sectional structure that is a combination of sloped and stepped shapes.

17. The grid for the large linear charged particle beam source according to claim 12, wherein the unit grid modules further comprise additional grid holes positioned in upper or lower regions of the connection portion of the unit grid modules, and
the additional grid holes are configured to compensate for the grid holes lost at the connection portions of the unit grid modules.

18. A large linear TCP source comprising:
a plasma vacuum chamber with a first opening on its upper surface;
a vacuum chamber flange having multiple second openings for mounting unit TCP sources, being larger than the first opening of the plasma vacuum chamber and mounted on the upper surface of the plasma vacuum chamber with the first opening; and
multiple unit TCP sources including a main body configured to generate plasma and a source flange mounted on the upper portion of the main body,
wherein the second openings of the vacuum chamber flange are positioned on the upper portion of the source flange of the unit TCP sources and the unit TCP sources are fixedly mounted to the lower surface of the vacuum chamber flange, such that the unit TCP sources are mounted inside the plasma vacuum chamber.

19. The large linear TCP source according to claim 18, further comprising a magnetic field reinforcement module which is positioned in a predetermined area inside or outside the plasma vacuum chamber to supplement magnetic field in the plasma region.

20. The large linear TCP source according to claim 18, wherein the magnetic field reinforcement module is composed of magnets placed either inside or outside the vacuum chamber at the connection portions of the unit TCP sources, or
the magnetic field reinforcement module is composed of electromagnets formed by coils surrounding the outside of the vacuum chamber at the connection portions of the unit TCP sources.
